(19) United States
(12) Patent Application Publication
(10) Pub. No.: US 2026/0324021 A1
(43) Pub. Date: Oct. 15, 2026

(54) STRUCTURES FOR A POWER DEVICE HAVING CO-DOPED SEMICONDUCTOR LAYERS

(71) Applicant: GlobalFoundries U.S. Inc., Malta, NY (US)

(72) Inventor: James A. Cooper, Santa Fe, NM (US)

(21) Appl. No.: 19/178,967

(22) Filed: Apr. 15, 2025

(51) Int. Cl. H10D 62/13; H10D 30/01; H10D 30/66; H10D 62/832; H10D 62/834

(52) U.S. Cl. CPC H10D 62/153; H10D 30/0291; H10D 30/66; H10D 62/8325; H10D 62/834

(57) ABSTRACT

Structures for a power device and methods of forming a structure for a power device. The structure comprises a semiconductor substrate, a semiconductor layer on the semiconductor substrate, and a conductor layer that overlies a portion of the semiconductor layer. The semiconductor substrate and the semiconductor layer have the same conductivity type. The semiconductor layer comprises a first concentration of a first dopant species and a second concentration of a second dopant species. The first dopant species and the second dopant species have the same polarity. The first dopant species has a first ionization energy, the second dopant species has a second ionization energy, and the first ionization energy is greater than the second ionization energy.

This invention was made with government support under HQ0727790700 awarded by the Defense Microelectronics Activity. The government has certain rights in the invention.

### BACKGROUND

The disclosure relates to semiconductor devices and integrated circuit manufacture and, more specifically, to structures for a power device and methods of forming a structure for a power device.

Wide bandgap semiconductors, such as silicon carbide, may be used in high-power applications, such as power converters, motor inverters, and motor drivers. Silicon carbide is well suited for power devices because of advantageous properties, such as a high saturated drift velocity, a high critical field strength, an exceptional thermal conductivity, and a significant mechanical strength. The advantageous properties of silicon carbide may be leveraged to construct a power device that is characterized by high reliability and high efficiency when operating at a high voltage.

Improved structures for a power device and methods of forming a structure for a power device are needed.

### SUMMARY

In an embodiment of the invention, a structure for a power device is provided. The structure comprises a semiconductor substrate, a semiconductor layer on the semiconductor substrate, and a conductor layer that overlies a portion of the semiconductor layer. The semiconductor substrate and the semiconductor layer have the same conductivity type. The semiconductor layer comprises a first concentration of a first dopant species and a second concentration of a second dopant species. The first dopant species and the second dopant species have the same polarity. The first dopant species has a first ionization energy, the second dopant species has a second ionization energy, and the first ionization energy is greater than the second ionization energy.

In an embodiment of the invention, a method of forming a structure for a power device is provided. The method comprises forming a semiconductor layer on a semiconductor substrate, and forming a conductor layer that overlies a portion of the semiconductor layer. The semiconductor layer and the substrate have the same conductivity type. The semiconductor layer comprises a first concentration of a first dopant species and a second concentration of a second dopant species. The first dopant species and the second dopant species have the same polarity. The first dopant species has a first ionization energy, the second dopant species has a second ionization energy, and the first ionization energy is greater than the second ionization energy.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a structure in accordance with embodiments of the invention.

FIG. 2 is a cross-sectional view of a structure in accordance with embodiments of the invention.

### DETAILED DESCRIPTION

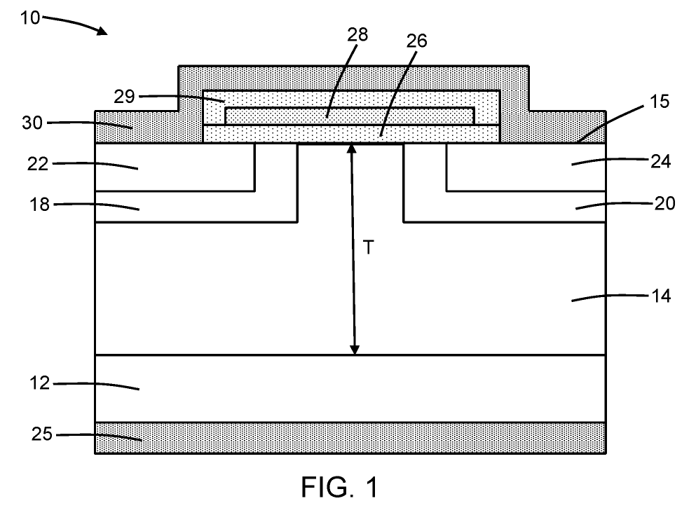

With reference to FIG. 1 and in accordance with embodiments of the invention, a structure 10 for a power device, such as a metal-oxide-semiconductor field-effect transistor, may be formed using a semiconductor substrate 12 and a semiconductor layer 14. In an embodiment, the semiconductor layer 14 may be formed by epitaxial growth on the semiconductor substrate 12. In an embodiment, the semiconductor substrate 12 and the semiconductor layer 14 may be comprised of a wide bandgap semiconductor material. In an embodiment, the semiconductor substrate 12 and the semiconductor layer 14 may be comprised of a semiconductor material having a bandgap greater than the bandgap of silicon. In an embodiment, the wide bandgap semiconductor material may be silicon carbide. In an embodiment, the wide bandgap semiconductor material may be gallium nitride. In an alternative embodiment, the semiconductor substrate 12 and the semiconductor layer 14 may be comprised of silicon.

A well 18 and a well 20 are formed in portions of the semiconductor layer 14. The wells 18, 20 may be formed by introducing a dopant of a given conductivity type by, for example, ion implantation into the semiconductor material of the semiconductor layer 14. An implantation mask may be formed to define selected areas on a top surface 15 of the semiconductor layer 14 that are exposed for the implantation of ions. The implantation mask may include a hardmask that is applied and patterned to form an opening exposing the selected areas on the top surface 15 and determining, at least in part, the location and horizontal dimensions of the wells 18, 20. The implantation conditions, such as ion species, dose, kinetic energy, and substrate temperature, may be selected to tune the electrical and physical characteristics of the wells 18, 20, to minimize defects, and to maximize the ionization and activation of the implanted dopants. In an embodiment, the ion implantation may be performed at substrate temperature in a range of 25°C to 600°C. The implantation mask, which is compatible with the implantation conditions and is stripped following implantation, has a thickness and stopping power sufficient to block the implantation of ions in masked areas. In an embodiment, the wells 18, 20 may be doped with a concentration of a p-type dopant (e.g., aluminum) to provide p-type electrical conductivity.

Doped regions 22, 24 are formed in portions of the semiconductor layer 14 and, more specifically, respectively inside the boundaries of the wells 18, 20. The doped regions 22, 24 may be formed by introducing a dopant of a given conductivity type by, for example, ion implantation into the semiconductor material of the semiconductor layer 14. An implantation mask may be formed to define selected areas on the top surface 15 that are exposed for the implantation of ions. The implantation mask may include a hardmask that is applied and patterned to form an opening exposing the selected areas on the top surface 15 and determining, at least in part, the location and horizontal dimensions of the doped regions 22, 24. The implantation conditions, such as ion species, dose, kinetic energy, and substrate temperature, may be selected to tune the electrical and physical characteristics of the doped regions 22, 24. In an embodiment, the ion implantation may be performed at substrate temperature in a range of 25°C to 600°C. The implantation mask, which is compatible with the implantation conditions and is stripped following implantation, has a thickness and stopping power sufficient to block the implantation of ions in masked areas. The doped regions 22, 24 are characterized by an opposite electrical conductivity type from the wells 18, 20. In an embodiment, the doped regions 22, 24 may be doped (e.g., heavily doped) with a concentration of an n-type dopant (e.g., nitrogen) to provide n-type electrical conductivity.

A dielectric layer 26 is formed on a portion of the top surface 15 of the semiconductor layer 14, and a conductor layer 28 is formed on the dielectric layer 26. The dielectric layer 26 may be comprised of a dielectric material, such as silicon oxide (e.g., silicon dioxide), that is an electrical insulator. The conductor layer 28 may be comprised of a conductor, such as polysilicon heavily doped with an n-type dopant (e.g., phosphorus or arsenic).

A dielectric layer 29 may be formed that covers the conductor layer 28. The dielectric layer 29 may be comprised of a dielectric material, such as silicon dioxide, that is an electrical insulator. A metal layer 25 may be formed that provides a drain contact at the backside of the semiconductor substrate 12. A metal layer 30 may be formed that provides ohmic contacts to the doped regions 22, 24 and the wells 18, 20, and that is electrically isolated from the conductor layer 28 by the dielectric layer 29. The metal layer 30 may be comprised of one or more metals, such as aluminum and/or nickel.

The well 18 and the well 20 may operate as base regions of a power transistor. The portion of the semiconductor layer 14 laterally arranged between the well 18 and the well 20 may operate as a JFET region of the power transistor. The doped region 22 and the doped region 24, which are respectively arranged inside the wells 18, 20, may operate as source regions of the power transistor. The semiconductor substrate 12 may operate as the drain of the power transistor and may be contacted by, for example, a metal layer at the backside of the semiconductor substrate 12. The portion of the semiconductor layer 14 in a vertical direction between the wells 18, 20 and the semiconductor substrate 12 may operate as a drift region of the power transistor that has a doping concentration and a thickness appropriate to supply a desired blocking voltage. The conductor layer 28 may operate as a gate electrode of the power transistor, and the dielectric layer 26 may operate as a gate dielectric of the power transistor. The conductor layer 28 fully overlaps with the portion of the semiconductor layer 14 operating as the JFET region and also overlaps with portions of the doped regions 22, 24 and portions of the wells 18, 20 between the doped regions 22, 24 and the JFET region.

In an embodiment, the semiconductor substrate 12 and the semiconductor layer 14 may be comprised of silicon carbide that is doped with an n-type dopant to have n-type electrical conductivity. In an embodiment, the semiconductor substrate 12 and the semiconductor layer 14 may be comprised of silicon carbide that is doped to have n-type electrical conductivity with the semiconductor substrate 12 having a higher dopant concentration than the semiconductor layer 14.

The semiconductor layer 14 may be doped with concentrations of multiple dopant species with the same polarity, such as either n-type polarity or p-type polarity. In an embodiment, the semiconductor layer 14 may be doped with concentrations of multiple dopant species with n-type polarity and may contribute free conduction electrons. In an embodiment, the multiple dopant species may be uniformly distributed across the thickness T of the semiconductor layer 14. In an embodiment, the multiple dopant species may be distributed with substantial uniformity across the thickness T of the semiconductor layer 14. In an embodiment, one or more of the multiple dopant species may be non-uniformly distributed across the thickness T of the semiconductor layer 14. For example, one or more of the dopant species may have a concentration that is highest at top surface 15 and that is lowest at the interface between the semiconductor layer 14 and the semiconductor substrate 12.

In an embodiment, the semiconductor layer 14 may be doped with a concentration of a dopant species having a comparatively lower ionization energy and a concentration of another dopant species having a comparatively higher ionization energy. In an embodiment, the semiconductor layer 14 may be doped with a concentration of a dopant species having an ionization energy that is less than or equal to 0.1 electron volts and a concentration of another dopant species having an ionization energy in a range of 0.2 electron volts to 0.3 electron volts. In an embodiment, the dopant species having the comparatively lower ionization energy and n-type polarity may be nitrogen and the dopant species having a comparatively higher ionization energy and n-type polarity may be lithium. In an embodiment, the dopant species having the comparatively lower ionization energy and n-type polarity may be nitrogen, the dopant species having a comparatively higher ionization energy may be lithium and n-type polarity, and the semiconductor layer 14 may be comprised of silicon carbide. In an embodiment, the dopant species having the comparatively lower ionization energy and n-type polarity may be phosphorus and the dopant species having a comparatively higher ionization energy and n-type polarity may be lithium. In an embodiment, the dopant species having the comparatively lower ionization energy and n-type polarity may be phosphorus, the dopant species having a comparatively higher ionization energy and n-type polarity may be lithium, and the semiconductor layer 14 may be comprised of silicon carbide.

In an embodiment, the concentration of the dopant species with the comparatively high ionization energy may be greater than the concentration of the dopant species with the comparatively low ionization energy. In an embodiment, the concentration of the dopant species with the comparatively high ionization energy may be less than the concentration of the dopant species with the comparatively low ionization energy. In an embodiment, the concentration of the dopant species with the comparatively high ionization energy may be equal to the concentration of the dopant species with the comparatively low ionization energy. In an embodiment, the semiconductor layer 14 may be comprised of the dopant species nitrogen and the dopant species lithium, both having n-type polarity, in respective concentrations having a ratio of about 24% nitrogen to about 76% lithium.

The co-doping of the semiconductor layer 14 with multiple dopant species may improve the performance of the power transistor embodied in the structure 10. When a silicon carbide-based power transistor is operating at around room temperature, almost all nitrogen donors are fully ionized and contribute free conduction electrons to the region. However, the mobility of conduction electrons decreases with temperature, which makes the specific on-resistance of the semiconductor layer 14 increase with temperature. Co-doping the semiconductor layer 14 with a combination of a dopant species characterized by a comparatively lower ionization energy and a dopant species characterized by a comparatively higher ionization energy may cause the power transistor to exhibit a change in specific on-resistance with increasing temperature that is substantially independent of temperature. As the operating temperature rises, the dopant species characterized by the comparatively higher ionization energy contributes additional conduction electrons that compensate for the decrease in drift mobility of conduction electrons. The total dopant concentration of all dopants in the semiconductor layer 14 may be selected to provide a blocking voltage required by a specific application for the power transistor. In embodiments, the total dopant concentration of all dopants in the semiconductor layer 14 may range from about 10¹⁴atoms per cubic centimeter to about 10¹⁶atoms per cubic centimeter.

In alternative embodiments, the co-doping may be applied to a different type of unipolar power device, such as a junction field-effect transistor, a Schottky diode, a junction barrier Schottky diode, or a merged PiN Schottky diode. In an alternative embodiment, the power transistor embodied in the structure 10 may be a trench power transistor in which the dielectric layer 26 and the conductor layer 18 are formed inside a trench that is patterned in the semiconductor layer 14. In an alternative embodiment, the power transistor embodied in the structure 10 may be a lateral power transistor in which the drift region and the drain electrode are positioned along an upper surface of the structure 10.

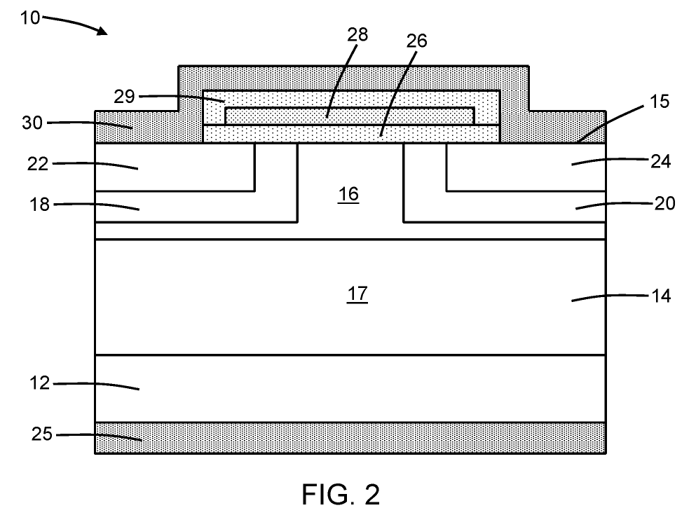

With reference to FIG. 2 and in accordance with alternative embodiments, the semiconductor layer 14 may have an upper portion 16 and a lower portion 17 between the upper portion 16 and the semiconductor substrate 12. The upper portion 16 and the lower portion 17 are arranged in a vertical direction between the top surface 15 and the semiconductor substrate 12.

In an embodiment, the upper portion 16 may have a higher dopant concentration of the multiple dopants than the lower portion 17. The upper portion 16 of the semiconductor layer 14 may have a lower electrical resistivity than the lower portion 17 of the semiconductor layer 14. The upper portion 16 of the co-doped semiconductor layer 14 may operate as a current spreading layer of the power transistor that is capable of decreasing specific on-resistance. In an embodiment, the boundary between the upper portion 16 and lower portion 17 may be arranged above the bottom of wells 18 and 20. In an embodiment, the boundary between the upper portion 16 and lower portion 17 may be aligned with the bottoms of wells 18 and 20. In an embodiment, the boundary between the upper portion 16 and lower portion 17 may be arranged below the bottoms of wells 18 and 20.

In an embodiment, the upper portion 16 of the semiconductor layer 14 may be doped with multiple dopant species in a given ratio and the lower portion 17 of the semiconductor layer 14 may be doped with multiple dopant species in a different given ratio. In an embodiment, the total dopant concentration of dopant species in the upper portion 16 of the semiconductor layer 14 may be equal to the total dopant concentration of dopant species in the lower portion 17 of the semiconductor layer 14. The upper portion 16 of the semiconductor layer 14 and the lower portion 17 of the semiconductor layer 14 may include different ratios of the dopant concentration of the dopant species characterized by a comparatively lower ionization energy (e.g., nitrogen or phosphorus) to the dopant concentration of the dopant species characterized by a comparatively higher ionization energy (e.g., lithium). For example, the total dopant concentration in the lower portion 17 may include a 90%:10% ratio of the dopant species characterized by a comparatively lower ionization energy to the dopant species characterized by a comparatively higher ionization energy, and the total dopant concentration in the upper portion 16 may include a 50%:50% ratio of the dopant species characterized by a comparatively lower ionization energy to the dopant species characterized by a comparatively higher ionization energy.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as an electronic power converter.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. A feature may “overlie” another feature if the feature is positioned in elevation over another feature. Different features may “overlap” if a feature extends over, and covers all or a part of, another feature. A feature may “underlie” another feature if the feature is positioned in elevation below another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a power device, the structure comprising:
a semiconductor substrate having a first conductivity type;
a semiconductor layer on the semiconductor substrate, the semiconductor layer having the first conductivity type; and
a conductor layer that overlies a portion of the semiconductor layer,
wherein the semiconductor layer comprises a first concentration of a first dopant species and a second concentration of a second dopant species, the first dopant species and the second dopant species having the same polarity, the first dopant species having a first ionization energy, the second dopant species having a second ionization energy, and the first ionization energy greater than the second ionization energy.

2. The structure of claim 1 further comprising:
a first well in the semiconductor layer, the first well having a second conductivity type opposite from the first conductivity type; and
a first doped region in the first well, the first doped region having the first conductivity type.

3. The structure of claim 2 wherein the semiconductor layer has a top surface, and the first doped region adjoins the top surface.

4. The structure of claim 2 wherein the semiconductor layer has a top surface, and further comprising:
a dielectric layer between the conductor layer and the top surface of the semiconductor layer.

5. The structure of claim 2 further comprising:
a second well in the semiconductor layer, the second well having the second conductivity type opposite from the first conductivity type; and
a second doped region within the second well, the second doped region having the first conductivity type,
wherein the portion of the semiconductor layer is laterally arranged between the first well and the second well.

6. The structure of claim 1 wherein the semiconductor substrate and the semiconductor layer comprise a wide bandgap semiconductor material.

7. The structure of claim 6 wherein the wide bandgap semiconductor material is silicon carbide.

8. The structure of claim 7 wherein the first dopant species is lithium, and the second dopant species is nitrogen.

9. The structure of claim 7 wherein the first dopant species is lithium, and the second dopant species is phosphorus.

10. The structure of claim 1 wherein the first dopant species is lithium, and the second dopant species is nitrogen.

11. The structure of claim 10 wherein the first concentration and the second concentration have a ratio of about 76% lithium to about 24% nitrogen.

12. The structure of claim 1 wherein the first dopant species is lithium, and the second dopant species is phosphorus.

13. The structure of claim 1 wherein the first dopant species and the second dopant species have n-type polarity.

14. The structure of claim 1 wherein the first concentration is greater than the second concentration.

15. The structure of claim 1 wherein the first concentration is less than the second concentration.

16. The structure of claim 1 wherein the first concentration is equal to the second concentration.

17. The structure of claim 1 wherein the first ionization energy is within a range of 0.2 electron volts to 0.3 electron volts, and the second ionization energy is less than or equal to 0.1 electron volts.

18. The structure of claim 1 wherein the semiconductor layer has a first portion with a first ratio of the first dopant species to the second dopant species, the semiconductor layer has a second portion with a second ratio of the first dopant species to the second dopant species, and the first ratio is greater than the second ratio.

19. The structure of claim 1 wherein the first concentration of the first dopant species and the second concentration of the second dopant species sum to about 10¹⁴ atoms per cubic centimeter to about 10¹⁶ atoms per cubic centimeter.

20. A method of forming a structure for a power device, the method comprising:
forming a semiconductor layer on a semiconductor substrate, wherein the semiconductor layer and the semiconductor substrate have a conductivity type; and
forming a conductor layer that overlies a portion of the semiconductor layer,
wherein the semiconductor layer comprises a first concentration of a first dopant species and a second concentration of a second dopant species, the first dopant species and the second dopant species have the same polarity, the first dopant species has a first ionization energy, the second dopant species has a second ionization energy, and the first ionization energy is greater than the second ionization energy.
